(19) United States
(12) Patent Application Publication
(10) Pub. No.: US 2024/0153762 A1
(43) Pub. Date: May 9, 2024

(54) WAFER FOR THE CVD GROWTH OF UNIFORM GRAPHENE AND METHOD OF MANUFACTURE THEREOF

(71) Applicant: Paragraf Limited, Somersham (GB)

(72) Inventors: Sebastian DIXON, Somersham (GB); Jaspreet KAINTH, Somersham (GB); Robert JAGT, Somersham (GB)

(73) Assignee: Paragraf Limited, Somersham (GB)

(21) Appl. No.: 18/283,728

(22) PCT Filed: Mar. 11, 2022
(86) PCT No.: PCT/EP2022/056398

§ 371 Date: Sep. 22, 2023

(30) Foreign Application Priority Data
Mar. 24, 2021 (GB) 2104140.5
Jul. 12, 2021 (GB) 2110031.8

(51) Int. Cl. H01L 21/02

(52) U.S. Cl. CPC H01L 21/02527; H01L 21/02008; H01L 21/02189; H01L 21/02205; H01L 21/0228; H01L 21/02488; H01L 21/02502

(57) ABSTRACT

A wafer for the CVD growth of uniform graphene and method of manufacture thereof There is provided a wafer for the CVD growth of uniform graphene at a temperature in excess of 700° C., the wafer comprising in order: a planar silicon substrate, an insulating layer provided across the silicon substrate, and a barrier layer provided across the insulating layer, wherein the insulating layer is a silicon nitride and/or aluminium nitride layer, and wherein the barrier layer has a constant thickness of 50 nm or less and provides a growth surface for the CVD growth of uniform graphene.

The present invention provides a wafer for the CVD growth of graphene. More particularly, the present invention provides a wafer that is suitable for growing uniform graphene at a temperature in excess of 700° C. The present invention also relates to a laminate comprising at least a portion of said wafer and a graphene layer formed thereon, in particular having been formed by CVD at a temperature in excess of 700° C. The present invention further provides methods for the manufacture of said wafer and said laminate.

Two-dimensional materials, of which graphene is one of the most prominent, are currently the focus of intense research. Graphene in particular has been shown, both theoretically and in recent years practically, to demonstrate extraordinary properties. The electronic properties of graphene are especially remarkable and have enabled the production of electronic devices which are orders of magnitude improved over non-graphene based devices. However, there remains a need in the art for wafers, also known as substrates, which facilitate the production of high-quality, uniform graphene. In particular, there remains a need for wafers in the microelectronics industry which are suitable for use in well-established semiconductor fabrication plants which may be used directly to grow graphene and then to manufacture graphene-based electronic devices on an industrial scale.

Semiconductor fabrications plants (also known as “fabs”) are factories wherein devices such as integrated circuits are manufactured. The cost of constructing and equipping a fab is typically many billions of dollars. In 2020, one fab was reported to have cost over $17 billion. Each fab is kitted out for specific manufacturing methods and has very little scope for the introduction of new technologies or methodologies. Typically, during the historical development of silicon based devices, new fabs have been constructed with each technological development to enable use of such new technology. Globally, fabs are therefore primarily constructed for the purpose of manufacturing electronics from silicon wafers.

It is known in the art that graphene may be synthesised, manufactured, formed, directly on non-metallic surfaces of substrates. These include silicon and sapphire along with other more exotic surfaces such as III-V semiconductors. The present inventors have found that the most effective method for manufacturing high-quality graphene, especially directly on such non-metallic surfaces, is that disclosed in WO 2017/029470. The method of WO 2017/029470 is ideally performed using an MOCVD reactor. Whilst MOCVD stands for metal organic chemical vapour deposition due to its origins for the purposes of manufacturing semiconductor materials such as AlN and GaN from metal organic precursors such as AlMe₃ (TMAI) and GaMe₃ (TMGa), such apparatus and reactors are well known and understood to those skilled in the art as being suitable for use with non-metal organic precursors. MOCVD may be used synonymously with metal organic vapour phase epitaxy (MOVPE).

Whilst there is a need to use silicon wafers in order to meet the strict requirements of pre-existing semiconductor fabrication plants, there is at the same time a need to grow graphene, an excellent conductor, directly on insulating surfaces for many electronic devices. It is known in the art that silicon wafers may be provided with insulating surfaces, for example, silicon having silicon oxide or silicon nitride surfaces (i.e. Si/SiO₂ or Si/SiNₓ wafers are well-known).

US 2005/142715 discloses a semiconductor device comprising a silicon substrate, a silicon oxide layer formed on the surface of said silicon substrates and a first oxide layer having a dielectric constant higher than silicon oxide formed above said silicon oxide layer. This disclosure is silent as to graphene growth.

US 2011/175060 discloses a substrate having a graphene film grown thereon, comprising a base substrate, a patterned aluminium oxide film and a graphene film preferentially grown on the patterned aluminium oxide film, wherein the base substrate may be a single crystalline silicon substrate having a silicon oxide film formed thereon.

US 2001/029092 relates to a method for forming a gate structure and is silent as to graphene growth; the method comprises thermally growing a thin silicon dioxide layer on top of a semiconductor device by using wet H₂/O₂ or a dry O₂, and then forming an aluminium oxide layer on top of the semiconductor device with doping a dopant in situ.

The inventors have sought to bridge the gap between the need for a silicon based wafer and an insulating surface for graphene growth to facilitate the adoption of graphene into industrial electronic device production, particularly in commercial fabs, and have as a result developed both improved wafers and methods for the manufacture of such wafers. The present invention therefore overcomes, or at least substantially reduces, the various problems associated with the prior art or at least provides a commercially useful alternative.

Accordingly, in a first aspect there is provided wafer for the CVD growth of uniform graphene at a temperature in excess of 700° C., the wafer comprising in order:
a planar silicon substrate,
an insulating layer provided across the silicon substrate, and
a barrier layer provided across the insulating layer,
wherein the insulating layer is a silicon nitride and/or aluminium nitride layer, and
wherein the barrier layer has a constant thickness of 50 nm or less and provides a growth surface for the CVD growth of uniform graphene.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present invention relates to a wafer. A wafer is a standard term in the art and is equivalent to a substrate. In this context, the wafer comprises multiple distinct layers (i.e. a silicon layer, insulating layer and barrier layer). Wafers are used for the fabrication and manufacture of electronic devices. Specifically, the wafer of the present invention is based on silicon such that the wafer is suitable for use in pre-existing fabs. In other words, the wafer of the present invention comprises a silicon substrate. The silicon substrate is planar being of substantially constant thickness and consisting of a single layer of elemental silicon. The silicon may however be doped, as is well-known in the art, with small amounts of other elements such as boron, nitrogen and phosphorus. When doped, the semiconductor substrate may be either p-type or n-type doped. Preferably, the doped semiconductor substrate has a dopant concentration of greater than 10¹⁵ cm⁻³, more preferably greater than 10¹⁶ cm⁻³ and/or less than 10²⁰ cm⁻³, preferably less than 10¹⁹ cm⁻³. A most preferred range is from 10¹⁶ cm⁻³ to 10¹⁸ cm⁻³. A silicon substrate may also include a CMOS substrate which is a silicon based substrate which includes various additional layers or circuitry embedded therein.

The wafer is suitable for the growth of uniform graphene by CVD at a temperature in excess of 700° C. Typically, graphene is grown at temperatures in excess of 700° C. when using CVD in order to achieve high quality and uniformity hence the need for a wafer suitable for such subsequent processing.

The inventors found that when using known hybrid wafers suitable for fabs such as Si/SiO₂, the conditions used to grow graphene on the insulating surface, in particular the high temperatures in excess of 700° C., resulted in damage of the insulating layer thereby reducing its function as an insulator. This effect is naturally more pronounced at the preferred higher growth temperatures such that the wafer of the present invention is preferably suitable for use at higher temperatures of greater than 800° C., greater than 900° C. and even more preferably greater than 1000° C., such as greater than 1100° C.

The wafer of the present invention has addressed this issue through the presence of both an insulating and barrier layer as described herein. Specifically, the wafer comprises a planar silicon substrate wherein an insulating layer is provided across the silicon substrate. Additionally, a barrier layer is provided across the insulating layer such that the wafer comprises these three layers in a specific order whereby the insulating layer is sandwiched between the planar silicon substrate and barrier layer whereupon graphene may be directly grown by CVD on the barrier layer. As a result, there are no intervening layers between those layers of the wafer or laminate as described herein. Thus, the layers may therefore be described as being directly on the relevant adjacent layers.

The insulating layer may in some aspects not be particularly limited. Accordingly, the conductivity of the insulating layer is less than that of silicon which is a semiconductor. For example, the conductivity of the insulator may be less than 10⁻⁶ S/cm, preferably less than 10⁻⁶ S/cm. Alternatively, this may be measured with respect to the materials band gap; silicon has a band gap of about 1.1 eV to about 1.6 eV whereas that of an insulator is much greater, typically greater than 3 eV, preferably greater than 4 eV.

In accordance with the first aspect, the insulating layer is silicon nitride and/or aluminium nitride. Such silicon wafers are well-known and commercially available. Equally, the insulating layer may be formed across a silicon substrate surface using conventional techniques. The thickness of the insulating layer is not particularly limited and a vast range of thicknesses, in for example Si/SiO₂ and Si/SiNₓ wafers, are available. The thickness may preferably be from 10 nm to 100 μm, such as from 20 nm to 10 μm. More preferably, the thickness is from 50 to 500 nm and in some embodiments, may be from 100 to 250 nm or from 100 to 200 nm. The advantages of the invention are most pronounced for thinner insulating layers in so far as the relatively thin barrier layer is sufficient to provide suitable insulation between the graphene and the silicon substrate without relying on the bulk of the insulating layer (e.g. 20 nm to 500 nm, 20 nm to 250 nm or preferably 20 nm to 200 nm). That is, there is an unexpected synergy between the combination of the insulating and the barrier layer as described herein that is preferably formed by ALD.

In an alternative aspect, the insulating layer is silicon oxide and the description which refers to silicon nitride and aluminium nitride may be construed as applying equally to silicon oxide. Whilst the inventors found further unexpected advantages when using silicon and/or aluminium nitride, a silicon oxide insulating layer was also advantageous in certain embodiments, in particular, those described herein with thin barrier layers (e.g. 5 nm or less), especially where the insulative layer is at least 10 nm thick. A combination of silicon oxide and silicon nitride and/or aluminium nitride may be preferable for certain embodiments, for example in silicon photonics for the production of electro-optic modulators wherein silicon nitride forms a waveguide within silicon oxide (thereby providing an insulating layer having regions of silicon nitride and silicon oxide, i.e. different surface regions upon which the barrier layer is provided as opposed to layers) or the insulating layer may consist of a layer of the nitride on a layer of silicon oxide.

The wafer further comprises a barrier layer provided across the insulating layer; the barrier layer is that of the wafer which provides a growth surface suitable for the CVD growth of uniform graphene. The barrier layer may also be referred to as a further insulating layer but is nevertheless distinct from the insulating layer on the silicon substrate. As will be appreciated, the opposite surface of the barrier layer is that in direct contact with and across the surface of the insulating layer below.

Furthermore, the barrier layer is relatively thin, at least with regards to the thickness of a standard silicon substrate, and has a constant thickness of 50 nm or less. As described herein, the thickness of the barrier layer may be at least 1 nm, or at least 2 nm. In some embodiments, the thickness of the barrier layer may therefore be from 1 to 10 nm, and preferably from 1 to 5 nm, from 2 to 10 nm or even from 2 to 5 nm, particularly for aluminium nitride insulating layers. In an exemplary embodiment, a silicon nitride insulating layer, for example having a thickness of from 10 to 50 nm, is combined with a barrier layer having a thickness of from 10 to 50 nm, preferably from 30 to 50 nm. In another exemplary embodiment, an aluminium nitride insulating layer, for example having a thickness of from 100 to 250 nm, is combined with a barrier layer having a thickness of 2 to 5 nm.

The barrier layer may be one or more of any of the metal oxides Al₂O₃, HfO₂, MgAl₂O₄, MgO, ZnO, Ga₂O₃, aluminium gallium oxide (AGO), TiO₂, SrTiO₃, LaAlO₃, Ta₂O₅, LiNbO₃, Y₂O₃, Y-stabilised ZrO₂ (YSZ), ZrO₂, Y₃Al₅O₁₂ (YAG), CeO₂ and/or h-BN, GaN, and/or SiC and/or CaF₂. Preferably, the barrier layer is Al₂O₃, HfO₂, MgAl₂O₄, MgO, Ga₂O₃, AGO, Ta₂O₅, Y₂O₃, Y-stabilised ZrO₂ (YSZ), ZrO₂, Y₃Al₅O₁₂ (YAG), CeO₂ and/or h-BN and/or CaF₂, more preferably alumina, yttria, zirconia and/or YSZ, most preferably alumina (and in some embodiments, alumina and/or hafnium oxide). All passages of the description herein of the barrier layer which refers to alumina and/or hafnium oxide should be construed as applying equally to a barrier layer formed from any these further materials and may in some embodiments be combined with alumina and/or hafnium oxide. Alumina and hafnium oxide may be referred to as Al₂O₃ or HfO₂, respectively, but it should be appreciated that the exact stoichiometry of these and the other materials disclosed herein may vary within normal bounds (and may therefore be referred to as, for example, AlOₓ).

Preferably, the barrier layer consists of one material, most preferably alumina. However, in some embodiments, the barrier layer may comprise multiple insulating layers, for example the barrier layer consists of one or more layers of alumina and one or more layers of hafnium oxide (provided the total thickness of the barrier layer is a constant thickness of less than 50 nm as described herein). Accordingly, the barrier layer may be a nanolaminate, such as an Al₂O₃—HfO₂ nanolaminate.

Without wishing to be bound by theory, the inventors believe that when growing graphene at temperatures in excess of 700° C., such as greater than 1000° C., in particular greater than 1100° C., the insulating layer can be damaged. Typically, graphene is grown using a hydrocarbon precursor, or at least an organic compound comprising carbon and hydrogen and/or with a carrier gas comprising hydrogen. The presence of hydrogen and radical hydrocarbon species in the reaction chamber during graphene growth may etch the insulating layer which has been found to reduce the function of the insulating layer as an effective insulator. Etching creates channels which can then become filled with conductive carbon during graphene growth providing a pathway for current to leak to the underlying silicon. The inventors have found that a barrier layer on the surface of the insulating layer can protect the insulation properties. The inventors were particularly surprised that this was true even for the small thicknesses described herein.

The inventors also found that silicon nitride and aluminium nitride offered an additional advantage over other insulative layers such as silicon oxide for a wafer that is to be used for the CVD growth of graphene at temperatures greater than 700° C., especially above 1000° C. or above 1100° C. At these relatively high growth temperatures, the inventors found that the silicon oxide surface can react with the silicon substrate to generate volatile species. For example, without wishing to be bound by theory, an insulating silicon dioxide layer can liberate silicon oxide gases (e.g. SiO), especially in the presence of hydrogen which may be liberated during graphene synthesis or included as an otherwise inert carrier gas. The formation of such gases was found to lead to damage in the insulative layer which otherwise can fill with conductive carbon providing a pathway for current leakage from the graphene to the underlying silicon substrate. Advantageously, the present invention avoids such a risk through the use of a silicon and/or aluminium nitride insulting layer.

The inventors also investigated whether a barrier layer could be provided directly on a silicon substrate. However, the inventors found that a lattice mismatch between silicon and the preferred barrier layers are a likely cause for defects/dislocations at the interface which may then spread through the layer, again providing a pathway within which conductive carbon may be filled during graphene growth thereby failing to provide graphene on an effective insulator.

Alumina and hafnium oxide are common materials for the formation of dielectric layers in electronic device fabrication. Such layers are ubiquitous in electronic devices and are known to be suitable materials to deposit on graphene, such as in the formation of a graphene transistor or as a protective layer in, for example, a graphene Hall-sensor. The barrier layer can be grown using ALD (atomic layer deposition). Other suitable techniques include physical vapour deposition methods such as sputtering, e-beam and thermal evaporation and chemical methods such as MOCVD. ALD is technique known in the art and comprises the reaction of at least two appropriate precursors in a sequential, self-limiting manner. Repeated cycles of the separate precursors allow the growth of a thin barrier layer due to the layer-by-layer growth mechanism which makes ALD particularly advantageous.

Despite the benefits afforded by ALD, the inventors found that thicker barrier layers, such as those greater than 50 nm, gave poor quality graphene. This was itself surprising since at least sapphire substrates (Al₂O₃) have been used by the inventors in a significant portion of their previous work to provide a non-metallic surface suitable for the growth of exceptionally high quality graphene. The thicker barrier layers were found to have a surface roughness greater than that of thinner barrier layers which then propagated through as defects in any graphene which was subsequently formed thereon. The inventors were surprised to find that a barrier layer as thin as less than 50 nm was sufficient to protect the insulative properties of the insulating layer and further was essential to facilitate the growth of graphene thereon at temperatures in excess of 700° C., more particularly greater than 1100° C.

Without wishing to be bound by theory, the inventors believe that by reducing the thickness of the barrier layer grown by ALD, the roughness arising from adjacent crystals of the polycrystalline alumina or hafnium oxide was reduced due to a reduction in the variation between different crystal sizes during growth of the barrier layer. However, there remains a balance in providing a barrier layer which comprises a larger crystal size. Generally, larger crystal sizes can be provided by growth of thicker barrier layers which also believed to influence graphene quality.

Accordingly, in a second aspect of the present invention, there is provided a method for the manufacture of a wafer for the CVD growth of uniform graphene at a temperature in excess of 700° C., the method comprising:
providing a planar silicon substrate having an insulating layer provided across a surface thereof,
forming a barrier layer across the insulating layer by ALD using water or ozone as an oxidant precursor,
wherein the insulating layer is a silicon nitride and/or aluminium nitride layer, and
wherein the barrier layer has a constant thickness of 50 nm or less and provides a growth surface for the CVD growth of uniform graphene at a temperature in excess of 700° C.

Preferably, the method is for the manufacture of a wafer according to the first aspect of the invention.

As described herein, the insulating layer may consist of silicon nitride and/or aluminium nitride. Accordingly, the insulating layer does not comprise silicon oxide and therefore, does not comprise any native surface oxides. In one embodiment of the present method, to remove the native oxides present on a silicon substrate the first step of providing a planar silicon substrate having an insulating layer comprises: heating a silicon substrate having native oxides in a reaction chamber to a temperature in excess of 900° C.; and contacting the surface with hydrogen gas to thereby remove native oxides. This method is especially preferred because it can be performed in-situ in the reaction chamber prior to formation of the insulative layer. It is fast, reliable and effective for removing the native oxides.

In this embodiment the hydrogen gas preferably consists of hydrogen. That is, the hydrogen is supplied with only unavoidable impurities. 99.99% purity hydrogen can be readily obtained. The hydrogen can be further purified by passing through a suitable purifier which removes trace organics, water and oxygen from the gas stream. A high purity source of hydrogen is required to ensure that there are no undesirable side reactions.

In an alternative embodiment, the first step comprises: treating a silicon substrate with hydrofluoric acid to thereby remove native oxides from the growth surface and introducing the silicon substrate into a reaction chamber for nitride formation. This method is less preferred because the silicon is reactive and precautions then have to be taken before the substrate is added to the reaction chamber. However, the use of hydrofluoric acid or equivalents serves to quickly remove the oxides without requiring a high temperature processing step.

In either case, the silicon nitride and/or aluminium nitride layer may then be formed using standard growth or deposition techniques.

The method involves forming a barrier layer across the insulating layer by ALD using water or ozone as a precursor, specifically as the source of oxygen atoms. The inventors found that when using water to form the barrier layer, thinner layers were particularly preferable, such as 1 to 50 nm, 1 to 10 nm, or 2 to 5 nm. Without wishing to be bound by theory, the inventors found that such thin layers have significantly reduced capability of H₂ pressure build up. Upon heating to the temperatures required for graphene growth, liberation of hydrogen gas resulted in blistering of the barrier layer surface. The roughening of the barrier layer impaired the quality of the graphene subsequently formed thereon. When using ozone as a precursor, the thickness of the barrier layer is preferably from 2 to 40 nm, preferably from 5 to 20 nm due to the slightly poorer insulative properties observed when using ozone as a precursor.

Accordingly, the step of forming a barrier layer is preferably performed using water as a precursor. Similarly, the wafer of the present invention preferably comprises a barrier layer which is obtainable, preferably obtained, by ALD using water as a precursor.

Suitable precursors which provide the required aluminium or hafnium atoms for alumina or hafnium oxide are well-known, commercially available and not particularly limited. Metal halides such as metal chlorides (e.g. AlCl₃ and HfCl₄) may be used. Alternatively, metal amides, metal alkoxides or organometallic precursors may be used. Hafnium precursors include, for example, tetrakis(dimethylamido)hafnium(IV), tetrakis(diethylamido)hafnium(IV), hafnium(IV) tert-butoxide and dimethylbis(cyclopentadienyl)hafnium(IV). Preferably, the barrier layer is alumina and preferably a further precursor for the ALD is a trialkyl aluminium or trialkoxide aluminium, such as trimethylaluminium, tris(dimethylamido)aluminium, aluminium tris(2,2,6,6-tetramethyl-3,5-heptanedionate) or aluminium tris(acetylacetonate). Suitable equivalent precursors for other barrier layers are also known.

The deposition temperature when forming the barrier layer may be any conventional temperature known in the art. Typically the deposition temperature is from 40° C. to 300° C., and the inventors have found that temperatures above 100° C. are preferable and afford better quality barrier layers.

In another aspect of the present invention, there is provided a method for the manufacture of a laminate, the method comprising providing a wafer described herein (or a portion thereof after dicing) and forming a graphene layer on the growth surface of the barrier layer by CVD at a temperature in excess of 700° C.

Thus, there is also provided a laminate comprising at least a portion of a wafer as described herein and a graphene layer formed on the growth surface of the barrier layer by CVD at a temperature in excess of 700° C.

As will be appreciated, the wafer may be diced using conventional techniques such as sawing or laser cutting thereby providing a plurality of diced wafers. A graphene layer may then be formed on the diced wafer by CVD as described herein to provide a laminate comprising a portion of the wafer.

Preferably, the graphene layer is formed by the CVD method described hereinbelow prior to wafer dicing. For example, a graphene layer is formed by CVD on a wafer having a diameter of at least 5 cm (2 inches). A plurality of electronic devices may then be formed using standard microfabrication techniques, the plurality of devices therefore sharing at least a common silicon substrate. The plurality of devices may then be separated by wafer dicing thereby providing electronic devices that each comprise a laminate that comprises a portion of the original wafer.

The present invention also provides an electronic device comprising a laminate as described herein. An electronic device is one which may then be installed into an electrical or electronic circuit, typically by wire bonding to further circuitry or by other methods known in the art such as soldering using “flip chip” style solder bumps. Thus an electronic device is a functioning device when installed in an electronic circuit and current is provided to the device. Preferred electronic devices are sensors such as Hall-sensors, current sensors and biosensors, modulators such as electro-optic modulators, and transistors. The present invention also provides the use of a laminate to form an electronic device. In some embodiments, the silicon substrate of the wafer of the laminate may be removed to afford an electronic device having no silicon substrate. This may be achieved through grinding or etching of the silicon in a process as described in UK Patent Application No. 2102218.1 (the contents of which is incorporated herein by reference).

The laminate and method for the manufacture of a laminate both require a graphene layer having been formed by CVD on the growth surface of the barrier layer of the wafer, wherein the graphene is grown by CVD at temperatures in excess of 700° C., preferably in excess of 1000° C., the wafer being suitable for such graphene growth by CVD at such temperatures.

Preferably, the graphene is grown by CVD in accordance with the disclosure of WO 2017/029470 (the contents of which is incorporated herein by reference). This publication discloses methods for manufacturing graphene; principally these rely on heating a substrate (such as a wafer as described herein) held within a reaction chamber to a temperature that is within a decomposition range of a carbon based precursor for graphene growth, introducing the precursor into the reaction chamber through a relatively cool inlet so as to establish a sufficiently steep thermal gradient that extends away from the substrate surface towards the point at which the precursor enters the reactions chamber such that the fraction of precursor that reacts in the gas phase is low enough to allow the formation of graphene from carbon released from the decomposed precursor. Preferably the apparatus comprises a showerhead having a plurality of precursor entry points or inlets, the separation of which from the substrate surface may be varied and is preferably less than 100 mm.

Forming graphene is synonymous with synthesising, manufacturing, producing and growing graphene. Graphene is a very well-known two-dimensional material referring to an allotrope of carbon comprising a single layer of carbon atoms in a hexagonal lattice. Graphene, as used herein, refers to one or more layers of graphene. Accordingly, some aspects of the present invention involve the formation of a monolayer of graphene as well as multilayer graphene (which may be termed a graphene layer structure). Preferably, graphene refers to a graphene layer structure having from 1 to 10 monolayers of graphene. In many subsequent applications for a laminate, a monolayer of graphene on a wafer is particularly preferred. Accordingly, the graphene formed is preferably monolayer graphene. Nevertheless, multilayer graphene is preferable for other applications and 2 or 3 layers of graphene may be preferred.

The method for the manufacture of a laminate comprises forming graphene by CVD which will take place in a CVD reaction chamber. This step of forming graphene will typically comprise introducing a precursor in a gas phase and/or suspended in a gas into the CVD reaction chamber. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. As will be appreciated, the wafer is, equally, preferably suitable for the growth of uniform graphene in accordance with the preferable CVD methods described herein.

Preferably, the method involves forming graphene by thermal CVD such that decomposition is a result of heating the precursor. Preferably, the CVD reaction chamber used is a cold-walled reaction chamber wherein a heater coupled to the substrate is the only source of heat to the chamber.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the wafer and the plurality of precursor entry points. As will be appreciated, by a constant separation it is meant that the minimum separation between the surface of the wafer and each precursor entry point is substantially the same. The minimum separation refers to the smallest separation between a precursor entry point and the wafer surface. Accordingly, such an embodiment involves a “vertical” arrangement whereby the plane containing the precursor entry points is substantially parallel to the plane of the wafer surface, i.e. the growth surface of the barrier layer.

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C.

Preferably, a combination of a sufficiently small separation between the wafer surface and the plurality of precursor entry points and the cooling of the precursor entry points, coupled with the heating of the wafer to with a decomposition range of the precursor and in excess of 700° C., generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform graphene directly on non-metallic substrates, preferably across the entire surface of the substrate. The wafer of the present invention may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the formation of graphene involves using a method as disclosed in WO 2017/029470, the formation of graphene comprises:
providing the wafer comprising a barrier layer having a growth surface on a heated susceptor in a close-coupled reaction chamber, the close-coupled reaction chamber having a plurality of cooled inlets arranged so that, in use, the inlets are distributed across the wafer and have constant separation from the wafer;
cooling the inlets to less than 100° C.;
introducing a precursor in a gas phase and/or suspended in a gas through the inlets and into the CVD reaction chamber to thereby decompose the precursor and form graphene on the growth surface of the barrier layer of the wafer; and
heating the susceptor to a temperature of at least 50° C. in excess of a decomposition temperature of the precursor, to provide a thermal gradient between the growth surface and inlets that is sufficiently steep to allow the formation of graphene from carbon released from the decomposed precursor;
wherein the constant separation is less than 100 mm, preferably less than 25 mm, even more preferably less than 10 mm.

In a preferred embodiment of the present invention, the precursor is introduced into the CVD reaction chamber as a mixture with a carrier gas. Carrier gases are well known in the art and may also be referred to as a dilution gas or a diluent. Carrier gases typically include inert gases such as noble gases, and in the case of graphene growth, hydrogen gas. Accordingly, the carrier gas is preferably one or more of hydrogen (H₂), nitrogen (N₂), helium (He), and argon (Ar). More preferably the carrier gas is one of nitrogen, helium and argon or the carrier gas is a mixture of hydrogen and one of nitrogen, helium and argon.

In another aspect of the present invention, there is provided a wafer for the CVD growth of uniform graphene at a temperature in excess of 700° C., the wafer comprising in order:
a planar silicon substrate,
an insulating layer provided across the silicon substrate, and
a barrier layer provided across the insulating layer,
wherein the barrier layer is an alumina and/or hafnium oxide layer, has a constant thickness of 20 nm or less and provides a growth surface for the CVD growth of uniform graphene.

Equally, in other aspects of the invention there is provided a method for the manufacture of a wafer for the CVD growth of uniform graphene at a temperature in excess of 700° C., the method comprising:
providing a planar silicon substrate having an insulating layer provided across a surface thereof,
forming a barrier layer across the insulating layer by ALD using water or ozone as a precursor,
wherein the barrier layer is an alumina and/or hafnium oxide layer, has a constant thickness of 20 nm or less and provides a growth surface for the CVD growth of uniform graphene at a temperature in excess of 700° C.; as well as a method for the manufacture of a laminate, the method comprising providing at least a portion of the wafer and forming a graphene layer on the growth surface of the barrier layer by CVD at a temperature in excess of 700° C.; together with such a laminate.

### FIGURES

The present invention will now be described further with reference to the following non-limiting Figures, in which:

FIG. 1 is a plot of resistance (Ω) against bias (V) for a comparative laminate.

FIG. 2 is a plot of resistance (Ω) against bias (V) for a laminate in accordance with the present invention.

FIG. 3A is an AFM image of graphene grown by a comparative method, direct onto a silicon nitride surface.

FIG. 3B is an AFM image of graphene grown by a comparative method, direct onto a silicon oxide surface.

FIG. 4 is an AFM image of graphene grown in accordance with the Example.

FIG. 5 is an AFM image of graphene grown in accordance with the Example.

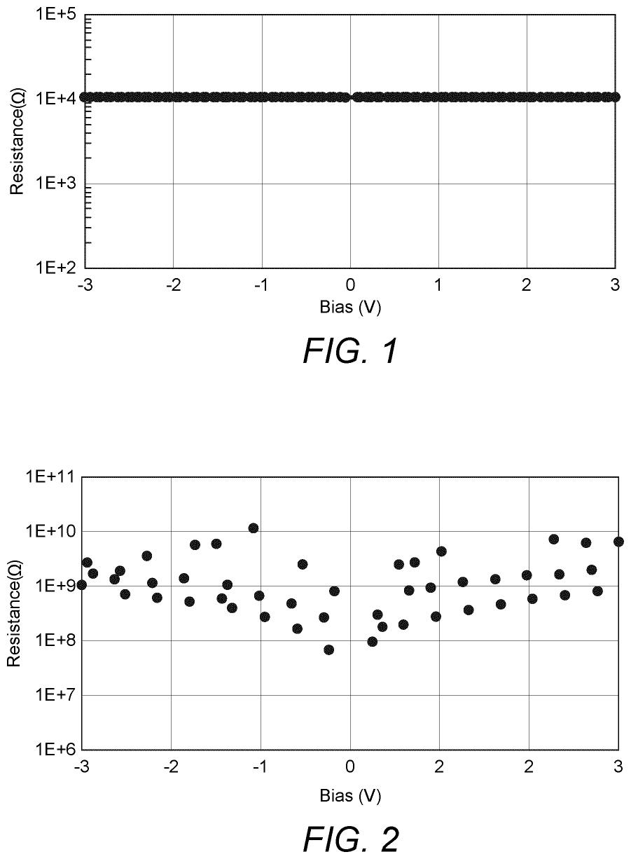

FIG. 1 is a plot of the data obtained from measuring the resistance between the graphene and the silicon substrate of a comparative wafer wherein the graphene was grown using CVD at a growth temperature in excess of 1300° C. on a 200 nm thick insulating Si₃Na layer of silicon substrate.

FIG. 2 is a plot of the data obtained from measuring the resistance between the graphene and the silicon substrate of a wafer as described herein. The wafer comprises an insulating Si₃Na layer on a silicon substrate, equivalent to that of the comparative example and further comprises a 5 nm AlOₓ barrier layer which had been formed by ALD using water as a precursor. The graphene was grown on the growth surface of the AlOₓ barrier layer using CVD at an equivalent growth temperature in excess of 1300° C. FIG. 2 demonstrates that the presence of a 5 nm AlOₓ barrier layer in a laminate affords an average 10⁵ improvement in resistance across a bias of from −3 V to +3 V as a result of the protection of the insulating Si₃Na layer during the process of graphene growth by CVD.

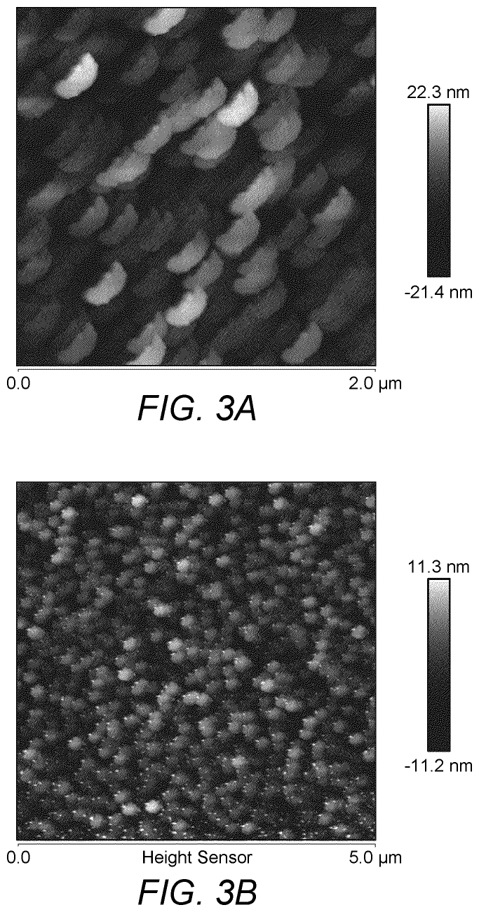

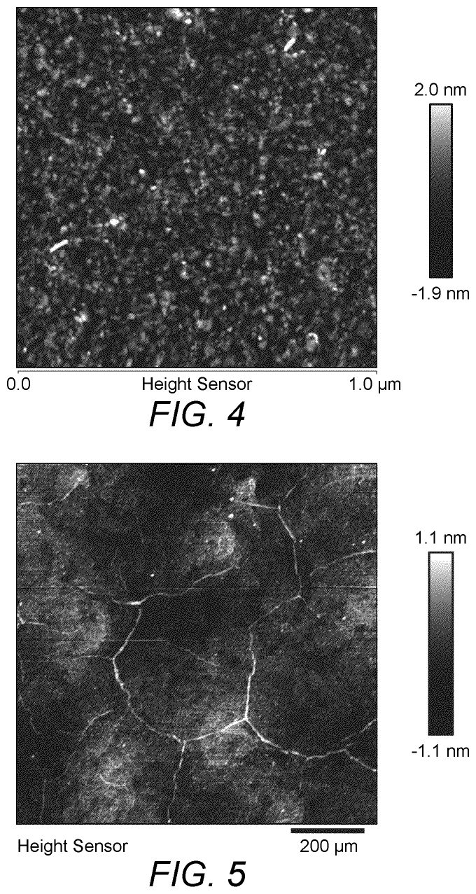

FIG. 3A is an AFM image which demonstrates the morphology of graphene grown directly onto a silicon nitride surface. FIG. 3B is an AFM image which demonstrates the morphology of graphene grown directly onto a silicon oxide surface. FIG. 4 is an AFM image which demonstrates the improved morphology of graphene grown in accordance with the method of the present invention, specifically grown onto a thin (<5 nm) alumina layer on silicon nitride. FIG. 5 is an AFM image which demonstrates the improved morphology of graphene grown in accordance with the method of the present invention, specifically grown onto a thin (<5 nm) alumina layer on aluminium nitride.

### EXAMPLES

The silicon wafer with a pre-grown silicon nitride or aluminium nitride coating is placed into an ALD chamber and held in the chamber at the deposition temperature of 150° C. under a vacuum of approximately 220 mTorr (about 27 Pa) with a nitrogen gas flow of 27 sccm to equilibrate the chamber temperature and pressure, as well as desorb any moisture from the sample surface. Al₂O₃ is then deposited using trimethyl aluminium (TMAI) and either deionised water (DI H₂O) or ozone (O₃) as the metalorganic and oxidant precursor, respectively, which are introduced into the deposition chamber using nitrogen as both the carrier and purge gas. The precursors are pulsed into the chamber in a 3:2 ratio, with pulse times of 0.6 seconds and purge times of 20 and 18 or 25 seconds for TMAI and DI H₂O or O₃, respectively. Films are deposited at 150° C. with varying numbers of cycles (between 10 and 1000 cycles) depending on the desired film thickness.

The ALD-capped wafers are positioned upon a silicon carbide-coated graphite susceptor within an MOCVD reactor chamber. The reactor chamber itself is protected in an inert atmosphere within a glovebox. The reactor is then sealed closed and purged under a flow of nitrogen, argon or hydrogen gas at a rate of 10,000 to 60,000 sccm. The susceptor is rotated at a rate of 40 to 60 rpm. The pressure within the reactor chamber is reduced to 30 to 100 mbar. An optical probe is used to monitor the wafer reflectivity and temperature during growth—with the wafers still in their unheated state, they are rotated under the probe in order to establish a baseline signal. The wafers are then heated using resistive heater coils positioned beneath the susceptor to a setpoint of from 1000 to 1500° C. at a rate of 0.1 to 3.0 K/s. The wafers are optionally baked under flow of hydrogen gas for from 10 to 60 min, after which the ambient gas is switched to nitrogen or argon and the pressure is reduced to 30 to 50 mbar. The wafer is annealed at the growth temperature and pressure for a period of from 5 to 10 min, after which a hydrocarbon precursor is admitted to the chamber. This is transported from its liquid state in a bubbler by passing a carrier gas (nitrogen, argon or hydrogen) through the liquid which is held under constant temperature and pressure. The vapour enters a gas mixing manifold and proceeds to the reactor chamber through a showerhead via a multitude of small inlets commonly referred to in the art as plenums/plena, which guarantees uniform vapour distribution and growth across the surface of the wafers. The wafers are exposed to the hydrocarbon vapour under constant flow, pressure and temperature for a duration of 1,800 to 10,800 s at which point the precursor supply valve is shut off. The wafers are then cooled under continuing flow of nitrogen, argon or hydrogen gas at a rate of from 0.1 to 4 K/min. Once the wafer temperature reaches below 200° C., the chamber is pumped to vacuum and purged with inert gas. The rotation is stopped and the heaters are shut off. The reactor chamber is opened and the graphene-coated wafers are removed from the susceptor once the heater temperature reaches below 150° C.

The graphene formed was then characterised using standard techniques including Raman spectroscopy and atomic force microscopy. FIGS. 3A and 3B show the morphology of graphene grown direct onto silicon nitride and silicon oxide surfaces, respectively. In contrast, FIGS. 4 and 5 show the morphology of graphene grown in accordance with the Example onto a thin (<5 nm) alumina layer grown on silicon nitride or aluminium nitride, respectively. Rather than growing as discrete strands or flakes of graphene, it grows as a continuous single layer, making it useful for application in electronic devices. Crucially, the alumina barrier also retains the insulating behaviour of the dielectric beneath, allowing the graphene to be gated via a field-effect. In the absence of the alumina barrier, the graphene growth degrades the insulating dielectric, and creates electrical contact between the graphene layer and the silicon wafer beneath.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “below”, “beneath”, “lower”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a wafer or device as described herein is turned over, elements described as “below” or “beneath” other elements or features would then be oriented “above” the other elements or features. Thus, the example term “below” can encompass both an orientation of above and below. The wafer or device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A wafer for the CVD growth of uniform graphene at a temperature in excess of 700° C., the wafer comprising in order:
a planar silicon substrate,
an insulating layer provided across the silicon substrate, and
a barrier layer provided across the insulating layer,
wherein the insulating layer is a silicon nitride and/or aluminium nitride layer, and
wherein the barrier layer has a constant thickness of 50 nm or less and provides a growth surface for the CVD growth of uniform graphene.

2. The wafer according to claim 1, wherein the barrier layer is an alumina, yttria, zirconia and/or YSZ layer.

3. The wafer according to claim 1, wherein the insulating layer has a constant thickness of from 10 nm to 100 μm.

4. The wafer according to claim 1, wherein the barrier layer has a constant thickness of from 1 to 10 nm.

5. The wafer according to claim 1, wherein the barrier layer is obtainable by ALD using water or ozone as a precursor.

6. A laminate comprising at least a portion of the wafer according to claim 1 and a graphene layer formed on the growth surface of the barrier layer by CVD at a temperature in excess of 700° C.

7. An electronic device comprising the laminate of claim 6.

8. A method for the manufacture of a wafer for the CVD growth of uniform graphene at a temperature in excess of 700° C., the method comprising:
providing a planar silicon substrate having an insulating layer provided across a surface thereof,
forming a barrier layer across the insulating layer by ALD using water or ozone as a precursor,
wherein the insulating layer is a silicon nitride and/or aluminium nitride layer, and
wherein the barrier layer has a constant thickness of 50 nm or less and provides a growth surface for the CVD growth of uniform graphene at a temperature in excess of 700° C.

9. The method according to claim 8, wherein the barrier layer is an alumina, yttria, zirconia and/or YSZ layer.

10. The method according to claim 9, wherein the barrier layer is alumina and a further precursor for the ALD is a trialkyl aluminium or trialkoxide aluminium.

11. A wafer prepared according to the method of claim 8, wherein the wafer comprises in order:
a planar silicon substrate,
an insulating layer provided across the silicon substrate, and
a barrier layer provided across the insulating layer,
wherein the insulating layer is a silicon nitride and/or aluminium nitride layer, and
wherein the barrier layer has a constant thickness of 50 nm or less and provides a growth surface for the CVD growth of uniform graphene.

12. A method for the manufacture of a laminate, the method comprising:
providing the wafer of claim 1, and
forming a graphene layer on the growth surface of the barrier layer by CVD at a temperature in excess of 700° C.

13. A method for the manufacture of a laminate, the method comprising:
providing the wafer prepared according to the method of claim 8, and
forming a graphene layer on the growth surface of the barrier layer by CVD at a temperature in excess of 700° C.

14. The method according to claim 10, wherein the further precursor for the ALD is trimethylaluminium, tris(dimethylamido)aluminium, aluminium tris(2,2,6,6-tetramethyl-3,5-heptanedionate) or aluminium tris(acetylacetonate).
